(19) United States
(12) Patent Application Publication
(10) Pub. No.: US 2015/0228649 A1
(43) Pub. Date: Aug. 13, 2015

(54) TRANSISTOR WITH WELL TAP IMPLANT

(71) Applicant: GLOBALFOUNDRIES Inc., Grand Cayman (KY)

(72) Inventors: Jagar Singh, Clifton Park, NY (US); Andy Wei, Queensbury, NY (US)

(73) Assignee: GLOBALFOUNDRIES Inc., Grand Cayman (KY)

(21) Appl. No.: 14/176,660

(22) Filed: Feb. 10, 2014

(51) Int. Cl. H01L 27/088; H01L 29/66; H01L 21/283; H01L 21/8234

(52) U.S. Cl. CPC H01L 27/0886; H01L 27/088; H01L 21/823431; H01L 21/823493; H01L 29/66545; H01L 21/823437; H01L 21/283

(57) ABSTRACT

A fin of a FinFET, being p or n-type, includes a well encompassing the active region, the well being of the opposite type than the fin. An implant of the same type as the well is provided for the well tap at an edge of the active region. A dummy gate material on the fin between the source/drain and the well tap implant reduces an inherent resistance of a well tap contact.

### BACKGROUND OF THE INVENTION

1. Technical Field

The present invention generally relates to semiconductor transistors and methods of fabricating semiconductor transistors, and more particularly, to well taps in a semiconductor transistor and methods of fabricating well taps in a semiconductor transistor.

2. Background Information

As the density of integrated circuits increases, and the corresponding size of circuit elements decreases, circuit performance may be degraded by large amounts of current being drawn from the device power supply, resulting in a phenomenon commonly referred to as “latch-up.” As is known, latch-up may cause irreversible damage to the performance of integrated circuits. Hence, a need continues to exist for better protection of integrated circuits against such “latch-up.”

### SUMMARY OF THE INVENTION

The shortcomings of the prior art are overcome and additional advantages are provided through the provision, in one aspect, of a method of fabricating a well tap in a semiconductor transistor. The method comprises providing a semiconductor structure, the structure including a semiconductor substrate, wherein the substrate is one of p-type and n-type; defining an active region in the semiconductor structure; creating a well in the semiconductor structure encompassing the active region by adding one or more impurities, the well of a type opposite the one of p-type and n-type; and creating a well tap in the well by adding one or more additional impurities of a same type as the well at an edge of the active region.

In accordance with another aspect, a semiconductor device including a semiconductor structure, including a substrate of n-type or p-type; an active region in the semiconductor structure; a well of a type opposite the substrate, the well encompassing the active region; and a well tap of a same type as the well, the well tap situated in the well at an edge of the active region.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional elevational view of one example of a semiconductor structure obtained at an intermediate stage of fabrication of one or more integrated circuits, the semiconductor structure including a semiconductor substrate and a well tap created for a defined active region of the semiconductor substrate, in accordance with one or more aspects of the present invention.

FIG. 2 is an alternate embodiment of the structure of FIG. 1, with a dummy gate and dummy well taps, in accordance with one or more aspects of the present invention.

FIG. 3 depicts a top-down layout view of the structure of FIG. 1, with continuous metal contact spans created for source and drain regions, in accordance with one or more aspects of the present invention.

FIG. 4 depicts a top-down layout view of the structure of FIG. 1, with one or more breaks in metal contact spans created for the source and the drain regions, in accordance with one or more aspects of the present invention.

FIG. 5 depicts a top-down layout view of another example of a semiconductor structure incorporating aspects of the present invention.

FIG. 6 is a three-dimensional cross-sectional view of the structure of FIG. 5 taken across one of the raised structures or fins of FIG. 5.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

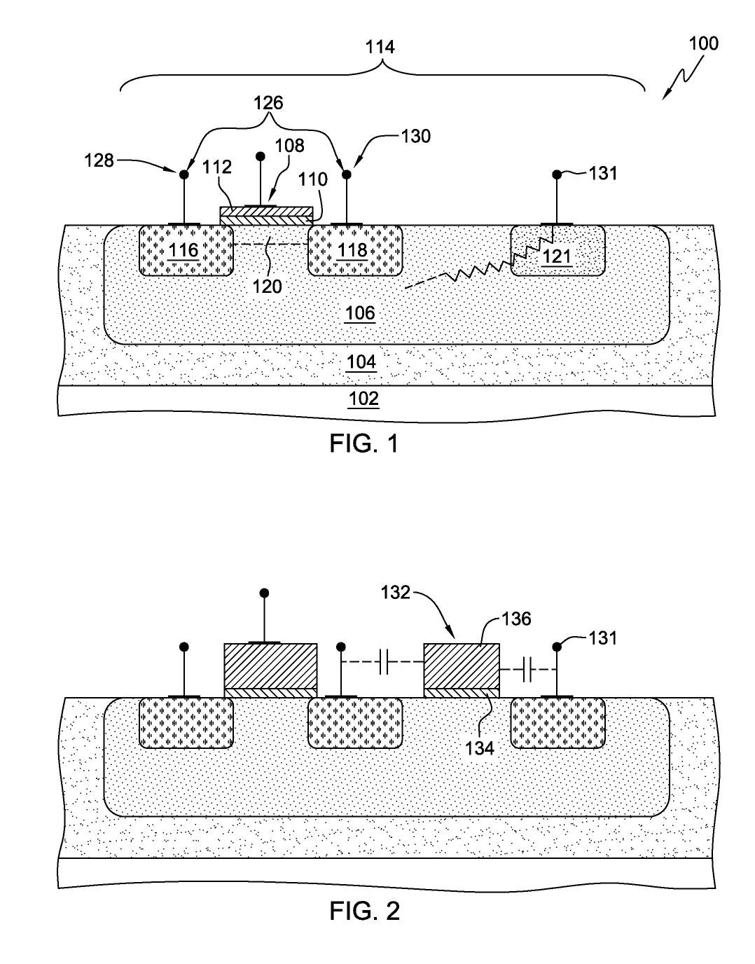

FIG. 1 is a cross-sectional elevational view of a semiconductor structure obtained at an intermediate stage of fabrication of one or more integrated circuits, in accordance with one or more aspects of the present invention. At the point of fabrication depicted in FIG. 1, semiconductor structure 100 includes a semiconductor substrate 102, for example, a bulk semiconductor material, e.g., a bulk silicon wafer. In one example, substrate 102 may include any silicon-containing substrate including, but not limited to, silicon (Si), single crystal silicon, polycrystalline silicon (Poly-Si), amorphous Si, silicon-on-nothing (SON), silicon-on-insulator (SOI), or silicon-on-replacement insulator (SRI) substrates and the like. Substrate 102 may in addition or instead include various isolations, dopings and/or device features. The substrate may include other suitable elementary semiconductors, such as, for example, crystalline germanium, a compound semiconductor such as silicon carbide (SiC), gallium arsenide (GaAs), gallium antimonide (GaSb), gallium phosphide (GaP), indium phosphide (InP), indium arsenide (InAs), and/or indium antimonide (InSb) or combinations thereof; an alloy semiconductor including GaAsP, AlInAs, GaInAs, GaInP or GaInAsP or combinations thereof. Substrate 102 may be a planar substrate, or three-dimensional, such as FINs or Nanowires.

Continuing with FIG. 1, in this example, semiconductor structure 100 may include a raised semiconductor structure coupled to semiconductor substrate 102. As used herein, the term “raised semiconductor structure” refers to a structure that is raised with respect to the substrate to which it is coupled, creating a three-dimensional structure (versus planar). In one example, such a raised structure takes the form of a “fin.” The raised semiconductor structure may include a p-type doped substrate 104, where a portion of the raised semiconductor structure may be implanted with a dopant such as, for example, a p-type dopant, to create the p-type doped substrate. Note that as used herein, p-type dopant refers to the addition of an impurity to the bulk semiconductor substrate to create deficiencies of valence electrons. Examples of a p-type dopant may include boron, aluminum, gallium or indium, being added to a portion of substrate 104. Alternatively, the raised semiconductor structure may instead include an n-type doped substrate, where a portion of the raised semiconductor structure may be implanted with a dopant such as, for example, n-type dopant, to create the n-type doped substrate. The n-type dopant refers to the addition of impurities to, for instance, an intrinsic semiconductor material of the substrate, which contribute more electrons to an intrinsic material, and may include (for instance) phosphorus, antimony or arsenic.

A portion of p-type substrate 104 may be provided with an n-type well 106, the well being of the opposite type as the raised structure substrate. The well may be created where a portion of p-type substrate 104 is implanted with an n-type dopant, to create the n-type well. Examples of an n-type dopant may include phosphorus, antimony or arsenic. As discussed above, the n-type dopant refers to the addition of impurities to, for instance, an intrinsic semiconductor material of the p-type substrate, which contribute more electrons to the intrinsic material. Although the present example includes n-type well 106 fabricated over p-type substrate 104, one skilled in the art will appreciate that a p-type well could instead be fabricated over an n-type raised semiconductor structure.

Continuing further with the example of FIG. 1, a gate structure 108 is included, which may be obtained during a replacement metal gate fabrication process. One skilled in the art will note that gate structure 108 may include a thin oxide layer 110 (also referred to as pad oxide) being typically disposed over the n-type well 106 (a channel region as explained more fully below), to protect the n-well during subsequent processing. A sacrificial gate material 112 such as, for example, amorphous silicon, may also be provided over the thin oxide layer, to hold the gate position for subsequent metal electrodes to be formed. A portion of the thin oxide layer and the sacrificial gate material may be patterned using conventional etching processes, to define gate structure 108 over n-type well 106. The etching processes may include conventional anisotropic dry etching processing, for example, reactive ion etching or isotropic wet etching processes.

An active region 114 is defined within the upper surface of semiconductor structure 100, adjoining gate structure 108. This active region 114 may be defined by creating regions of impurities in the upper surface of n-well 106, to provide a source region 116 and a drain region 118. One skilled in the art will know that creating such impurity regions may be performed by selectively exposing a given region, adjacent to gate structure 108 within n-well 106, and implanting the exposed portion with one or more dopants, such as one or more p-type dopants or one or more n-type dopants, depending on the semiconductor device to be fabricated. In one example, active region 114 within n-well 106 may be implanted with a p-type dopant, such as, for example, boron, aluminum, gallium or indium, to include p+ source region 116, p+ drain region 118, the region underlying gate structure 108 being a channel region 120 between the p+ source region and the p+ drain region.

Continuing further with FIG. 1, in accordance with one or more aspects of the present invention, a well-tap 121 may be provided by, for example, patterning and selectively implanting a portion of the upper surface of n-well 106 with one or more additional dopants to create the well-tap. One skilled in the art will know that, a well-tap being fabricated over p-type substrate may be connected to source voltage (V_{SS}) while a well-tap being fabricated over n-type substrate may be connected to drain voltage (V_{DD}) to prevent latch-up. Note that the additional dopants may be implanted using, for example, a conventional ion implantation process to create well-tap 121 and the additional dopant(s) may be of the same type as the well at an edge of active region 114. In one example, a portion of the upper surface of n-well 106 may be implanted with n-type dopants to create n-type well-tap 121 that is, in this example, laterally separated from drain region 118, for instance, at an edge of active region 114 to prevent latch-up. Examples of n-type dopants for the well tap may include phosphorus, arsenic or antimony. The fabrication may further proceed to create multiple contacts 126, for example, contacts 128, 130 and 131 to improve current handling.

Alternatively, as depicted in FIG. 2, an additional dummy gate structure 132 may be provided over active region 114, and more particularly, in an area between drain region 118, which is p-type, and well-tap 121, which is n-type. In one example, additional dummy gate structure 132 may include a thin oxide layer 134 (also referred to as pad oxide) disposed over active region 114, in the area between n-type doped well-tap 121 and p-type doped drain region 118, to reduce an inherent resistance of well-tap contact 131. A sacrificial gate material 136 such as, for example, amorphous silicon, may also be provided over thin oxide layer 134. In the example of FIG. 2, a gate-last process is used, and it will be understood that when gate structure 108 is replaced with metal, additional dummy gate structure 132 would also be replaced with metal.

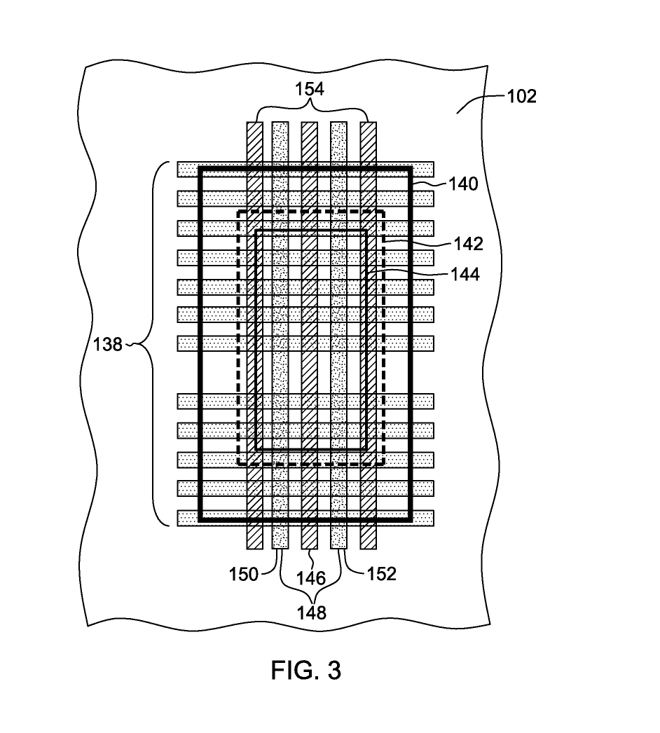

FIG. 3 depicts a top-down layout view of the structure of FIG. 1, and illustrates multiple raised semiconductor structures 138 that are parallel to one another, being coupled to semiconductor substrate 102. As discussed above, in one example, the one or more raised semiconductor structures may include an n-type doped well (also referred to herein as n-well 140), and may itself be implanted with a dopant such as, for example, an n-type dopant, to create the n-type doped substrate. The n-type dopant refers to the addition of impurities to, for instance, an intrinsic semiconductor material of the substrate, which contribute more electrons to an intrinsic material, and may include (for instance) phosphorus, antimony or arsenic. In another example, the raised semiconductor structure may instead include a p-type doped well (also referred to herein as p-well), and the raised semiconductor structure itself may be implanted with a dopant such as, for example, a p-type dopant, to create the p-type doped substrate. In such an example, p-type dopants including boron, aluminum, gallium or indium, may be added to a portion of raised semiconductor structures. A well tap 142 with additional implant may be provided at a top portion of n-well 140 within the one or more raised semiconductor structures 138, in accordance with one or more aspects of the present invention. In one example, the well tap implant may be of the same type as n-well 140.

As discussed above, a plurality of active regions 144 may be defined across a top portion of raised semiconductor structures 138. In one example, these active regions 144 may be defined by patterning an upper surface of the raised structures, to be selectively provided with a source region and a drain region. Although not depicted in the figure, in one example, active region 144 within n-well 140 may be selectively implanted with a p-type dopant, such as, for example, boron, aluminum, gallium or indium, resulting in a p+ source region, p+ drain region and a channel region between the p+ source region and the p+ drain region.

Continuing further with FIG. 3 dummy gate structure 146 is provided over and encompasses one or more raised semiconductor structures 138. Also provided over the raised structure(s) are multiple contacts 148, for example, source contact 150 and drain contact 152. As described above, although not viewable in a top-down figure, the gate structures may include a thin oxide layer (also referred to as pad oxide) disposed over the n-well, to reduce an inherent resistance of the well tap, described below. A sacrificial gate material such as, for example, amorphous silicon, may also be provided over the thin oxide layer, to hold the gate position for subsequent metal electrodes to be formed. Note that the dummy gates, source contacts and drain contacts span the length of the region, extending perpendicularly over all the raised semiconductor structures, without any breaks.

Similar to dummy gate 146, dummy lines 154 (for example, including a thin oxide layer) may be provided at an edge of active region 144 between drain contact 152 and well tap implant 142. The advantages of such dummy lines, and possible materials therefor, were noted with respect to FIG. 2.

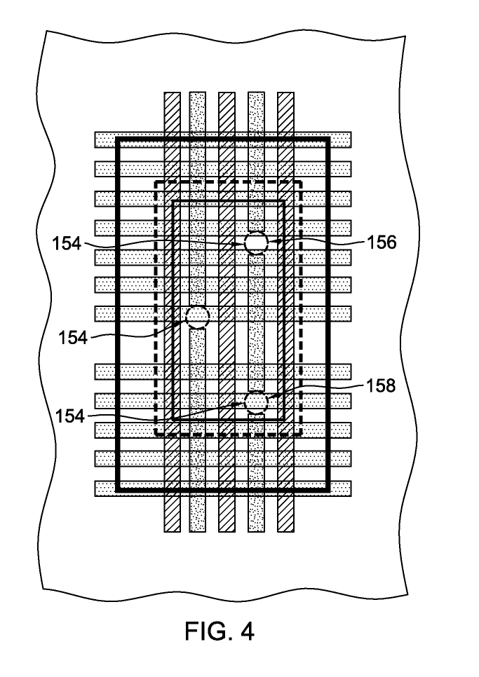

Alternatively, the source contact and the drain contact may have one or more breaks along their span across the raised structures, as depicted in FIG. 4. Note that, in one example, while gate structure 146 and well-tap span the length of the region, extending over entire raised semiconductor structure 138, source contact 150 and drain contact 152 may be patterned to have one or more breaks 154, for example, breaks 156 and 158. As one skilled in the art will know, the longer a contact line is, the more likely there is to form defects along the sides (e.g., line edge roughness). Thus, the breaks are preferred to reduce the chances of such defects.

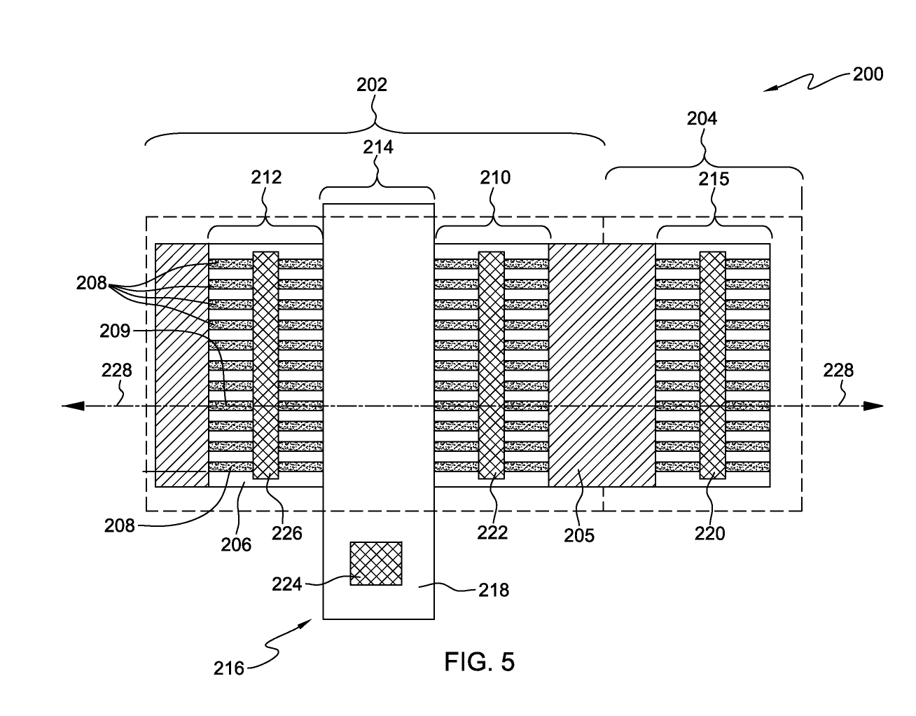

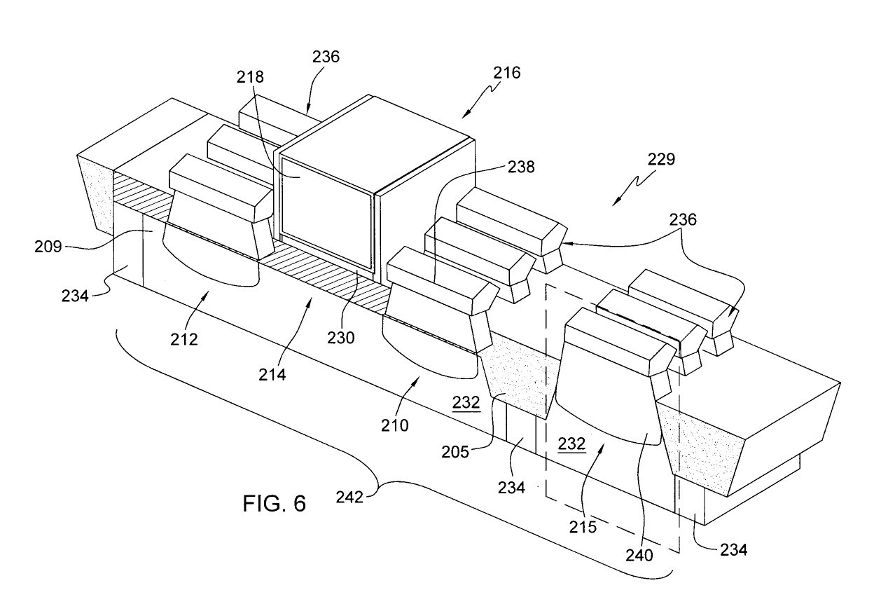

FIG. 5 depicts a top-down view of another example of a semiconductor structure 200 incorporating aspects of the present invention. In the example of FIG. 5, structure 200 includes an n-type semiconductor structure 202 and a p-type well tap 204. The n-type and p-type structures are separated by an isolation region 205, for example, a shallow trench isolation region (STI). Structure 200 includes a semiconductor substrate 206, for example, a bulk semiconductor material, e.g., a bulk silicon wafer. In one example, substrate 206 may include any silicon-containing substrate including, but not limited to, silicon (Si), single crystal silicon, polycrystalline silicon (Poly-Si), amorphous Si, silicon-on-nothing (SON), silicon-on-insulator (SOI), or silicon-on-replacement insulator (SRI) substrates and the like. Substrate 206 may in addition or instead include various isolations, dopings and/or device features. The substrate may include other suitable elementary semiconductors, such as, for example, crystalline germanium, a compound semiconductor such as silicon carbide (SiC), gallium arsenide (GaAs), gallium antimonide (GaSb), gallium phosphide (GaP), indium phosphide (InP), indium arsenide (InAs), and/or indium antimonide (InSb) or combinations thereof; an alloy semiconductor including GaAsP, AlInAs, GaInAs, GaInP or GaInAsP or combinations thereof. Substrate 206 may be a planar substrate, or three-dimensional, such as FINS or Nanowires.

Coupled to substrate 206 are a plurality of raised semiconductor structures 208, e.g., raised structure 209, taking the form of fins in one example. Each raised structure of n-type structure 202 includes, in the present example, a source region 210, a drain region 212 and a channel region 214 therebetween. In this top-down view, the channel region is covered by a gate structure 216 disposed perpendicular to the raised structures in this example, though it will be understood the gate structure placement with respect to the raised structures could be different. As best shown in FIG. 6, and described in more detail below, well tap 215 is created in p-type well 232, and additional p-type dopants 240 may be implanted therein at an edge of active region 242. Returning to FIG. 5, in the present example of a gate-last process, gate structure 216 includes a dummy or sacrificial gate material 218, such as, for example, amorphous silicon. Electrical connections to the various regions and gate structure are provided, for example, by contacts 220, 222, 224 and 226. The various portions of FIG. 5 described above may be conventionally fabricated using known techniques, for example, various maskings, depositions, implants and etchings, similar to that described with respect to FIGS. 1 and 2.

FIG. 6 is a three-dimensional cross-sectional view 229 of the structure 200 of FIG. 5, taken along line 228. Shown in FIG. 6 are several raised semiconductor structures beyond raised structure 209, which includes source region 210, drain region 212, channel region 214 and gate structure 216, which may include a thin oxide layer 230. The source, drain and channel regions are situated within a well 232, in this example, a p-type well or p-well. Although only partially shown in FIG. 6, the p-well 232 is itself situated within another well 234, in this example, an n-type well or n-well. The source, drain and well-tap contacts are not present in FIG. 6, in order to show semiconductor epitaxial growth 236 on top of the fins in the various regions, and on top of the epitaxial structures, conformal contacts 220, 222 and 224 (see FIG. 5) would be created. Although not necessary for the invention, epitaxial growth is preferred for the source, drain and well tap. In the present example, the epitaxial growth, e.g., growth 238 on top of fin 209, includes epitaxial silicon. As one skilled in the art will know, epitaxial silicon grows naturally into diamond shapes.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a semiconductor structure, the structure comprising a semiconductor substrate, wherein the substrate is one of p-type and n-type;
defining an active region in the semiconductor structure;
creating a well in the semiconductor structure encompassing the active region by adding one or more impurities, the well of a type opposite the one of p-type and n-type; and
creating a well tap in the well by adding one or more additional impurities of a same type as the well at an edge of the active region.

2. The method of claim 1, wherein the semiconductor structure comprises a planar transistor, and wherein creating the well and creating the well tap comprise creating the well and the well tap across a top portion of the substrate.

3. The method of claim 2, further comprising depositing a dummy gate material over the well tap.

4. The method of claim 3, wherein the active region comprises a source region, a drain region and a channel region therebetween, the method further comprising:
creating a dummy gate over the channel region; and
creating metal contacts over the source region and the drain region.

5. The method of claim 4, wherein the substrate comprises a bulk semiconductor material, wherein the defining comprises defining a plurality of active regions in the substrate, wherein creating the well and well tap comprises creating a well and well tap for each of the plurality of active regions in the substrate, and wherein the well taps, source contacts, drain contacts and dummy gates span the plurality of active regions, the method further comprising creating one or more breaks in the metal contact spans for the source regions and the drain regions.

6. The method of claim 5, further comprising replacing the dummy gate spans and dummy well taps with spans of one or more conductive materials.

7. The method of claim 4, further comprising replacing the dummy gate and the dummy well tap with one or more conductive materials.

8. The method of claim 1, wherein the semiconductor structure comprises a non-planar transistor, the semiconductor structure further comprising a raised semiconductor structure coupled to the substrate, wherein the defining comprises defining an active region across a top portion of the raised structure, and wherein creating the well and creating the well tap comprises creating the well and the well tap in the raised structure.

9. The method of claim 8, further comprising conformally depositing a dummy gate material about the well tap.

10. The method of claim 9, wherein the active region comprises a source region, a drain region and a channel region therebetween, the method further comprising:
creating a dummy gate encompassing the channel region; and
creating metal contacts encompassing the source region and the drain region.

11. The method of claim 10, wherein the substrate comprises a bulk semiconductor material, wherein the raised semiconductor structure comprises a plurality of raised semiconductor structures coupled to the substrate, wherein the defining comprises defining a plurality of active regions in the plurality of raised structures, wherein creating the well and well tap comprises creating a well and well tap for each of the plurality of active regions in the plurality of raised semiconductor structures, and wherein the well taps, source contacts, drain contacts and dummy gates span the plurality of active regions, the method further comprising creating one or more breaks in the metal contact spans for the source regions and the drain regions.

12. The method of claim 11, further comprising replacing the dummy gate spans and the dummy well taps with spans of one or more conductive materials.

13. The method of claim 10, further comprising replacing the dummy gate and the dummy well tap with one or more conductive materials.

14. A semiconductor device, comprising:
a semiconductor structure, comprising a substrate of n-type or p-type;
an active region in the semiconductor structure;
a well of a type opposite the substrate, the well encompassing the active region; and
a well tap of a same type as the well, the well tap situated in the well at an edge of the active region.

15. The semiconductor device of claim 14, wherein the device comprises a planar transistor, wherein the active region is situated across a top portion of the substrate, and wherein the well and the well tap are situated in the substrate.

16. The semiconductor device of claim 15, wherein the active region comprises a source region, a drain region and a channel region therebetween, the semiconductor device further comprising:
a dummy gate material over the channel region and the well tap; and
metal contacts over the source region and the drain region.

17. The semiconductor device of claim 16, wherein the substrate comprises a bulk semiconductor material, wherein the active region comprises a plurality of active regions, wherein the well and the well tap comprise a plurality of wells and well taps, each active region having a well and a well tap, wherein the dummy well taps, source contacts, drain contacts and dummy gates span a corresponding region of the wells and active regions, and wherein the source contact span and the drain contact span each have one or more breaks therein.

18. The semiconductor device of claim 15, wherein the active region comprises a source region, a drain region and a channel region therebetween, the semiconductor device further comprising:
a metal gate over the channel region; and
metal contacts over the well tap, the source region and the drain region.

19. The semiconductor device of claim 18, wherein the substrate comprises a bulk semiconductor material, wherein the active region comprises a plurality of active regions, wherein the well and the well tap comprise a plurality of wells and well taps, each active region having a pair thereof, wherein the metal well taps, source contacts, drain contacts and metal gates span the plurality of the active regions with one or more breaks in the source contact span and the drain contact span.

20. The semiconductor device of claim 14, wherein the semiconductor structure comprises a non-planar transistor, the semiconductor structure further comprising a raised semiconductor structure coupled to the substrate, wherein the active region comprises a source region, a drain region and a channel region therebetween, wherein the active region is situated across a top portion of the raised structure, wherein the well and the well tap are situated in the raised structure, and wherein the semiconductor structure further comprises:
a gate comprising metal encompassing the channel region; and
metal contacts encompassing the source region, the drain region and the well tap.
